(19) United States
(12) Patent Application Publication
(10) Pub. No.: US 2013/0000705 A1
(43) Pub. Date: Jan. 3, 2013

(54) PHOTOVOLTAIC DEVICE AND METHOD OF ITS FABRICATION

(75) Inventor: Joseph Shappir, Tel Aviv (IL)

(73) Assignees: YISSUM RESEARCH DEVELOPMENT COMPANY OF THE HEBREW UNIVERSITY OF JERUSALEM, LTD., Jerusalem (IL); SHENKAR COLLEGE OF ENGINEERING AND DESIGN, Ramat Gan (IL)

(21) Appl. No.: 13/516,430

(22) PCT Filed: Oct. 11, 2010
(86) PCT No.: PCT/IL2010/000824

§ 371 Date: Sep. 21, 2012

Related U.S. Application Data
(60) Provisional application No. 61/287,036, filed on Dec. 16, 2009.

(51) Int. Cl. H01L 31/0224; H01L 31/18; H01L 31/0236

(52) U.S. Cl. 136/255; 438/73; 257/E31.032

(57) ABSTRACT

A photovoltaic device is presented including one or more cell units. The photovoltaic device comprises a semiconductor substrate having a patterned light collecting surface defining an array of spaced-apart substantially parallel first grooves. Each of these first grooves has a bottom portion, comprising a bottom surface and side walls extending from the bottom portion and being substantially perpendicular to the surface of the device. A heavily doped semiconductor layer in the form of spaced-apart regions is located at the bottom surfaces of the first grooves respectively. Further improvement of performance is obtained by deposition of thin metal lines on top of the heavily doped spaced apart lines.

### FIELD OF THE INVENTION

This invention relates to a photovoltaic device and a method of its manufacture.

### BACKGROUND OF THE INVENTION

Photovoltaic devices are formed by an array of photovoltaic cells fabricated in semiconductor wafers with appropriate electrical connection between them forming a readout circuit that collects photocurrent generated by multiple cells of the same cell unit (array). The readout circuit includes metal conductors from which the electric current is further transferred via so-called bus lines. A major factor in the performance of a photovoltaic device is the shading of the active area of the cell unit (i.e. its light collection surface) by the metal conductors and the bus lines, which all extend on top of the light collecting surface. The larger the surface area covered by the metal lines (metal conductors), the smaller the active, light collection area of the device. On the one hand, increasing the spacing between the metal lines (metal conductors), in order to reduce the shading, results in an increase in the cell series resistance with the direct outcome of increased resistive power loss. On the other hand, decrease of the spacing between the metal lines results in lower resistive power loss at the expense of larger shading loss.

A solution to the above problem is to use device configurations in which all the metal lines are located at the back side of the multi-cell device. However, this solution has certain drawbacks. The short wavelength photo generated electrons close to the top surface of the cell have to diffuse to the bottom side of the p-substrate through the few hundred microns of the wafer thickness with the penalty of certain loss due to recombination, resulting in certain decrease of cell efficiency. This also involves a more complex manufacturing process accompanied by higher cell price, and difficulty in effective cooling of the cell from the back side, since direct connection of the cell back side to the metal block is problematic because both polarities' cell contacts are on the same back side. This problem is aggravated in the case of concentrating systems. As a result, most currently manufactured solar cells have a metal contact to the n+ layer at the front side with resulting resistive and shading losses of about 12%.

### GENERAL DESCRIPTION

There is a need in the art for a novel photovoltaic device which is configured for increasing the efficiency of photocurrent production. The configuration of the device of the present invention provides for desirably increased effective area for light collection (area of the outer, light collecting surface of the device, exposed to input light and capable of collecting the light), thus increasing the amount of collected light, as well as desirably reducing the total resistance within the device, thus facilitating the conversion of the collected light into the photocurrent. The present invention also provides for a cost effective technique for the fabrication of such a photovoltaic device, utilizing the general principles of lithography.

The main idea of the present invention is based on the understanding of the following. According to the conventional approach in the field of photovoltaic devices, a p-type wafer is formed with an upper n+ layer. The upper n+ layer is to be heavily doped to reduce the series resistance. This, however, reduces the lifetime of the photo generated carriers, thus less contributing to the generation of photocurrent. On the other hand, a lower level of doping results in higher series resistance, thus requiring smaller spaces between thick metals lines, typically about 1000 μm between the about 50 μm wide metal lines. As a result, about 5% of the surface of the device does not participate in the light collection being shaded by metal lines of the cells' readout circuit. As indicated above, these metal lines are further connected to one or more bus lines for transmitting electrical energy. The bus lines are wide wires, even wider than said metal lines. According to the conventional approach, the bus lines are also located within the surface area exposed to light, thus further shading a fraction of the effective area of the cell unit by about an additional 5%. The cumulative shading losses are accordingly about 10%.

According to the invention, the surface of a photovoltaic device (semiconductor wafer) is patterned to form an array of spaced-apart grooves, each having at least a bottom portion with side surfaces substantially perpendicular to the surface of the photovoltaic device. A photovoltaic cell structure (module) is created by providing a heavily doped semiconductor (typically n+) layer in the form of spaced-apart regions only inside the bottom portions of the grooves, while the rest of the photovoltaic cell's surface is doped with significantly lower concentration of n-type impurities, or it may be doped with p-type impurities. This configuration enables increased doping level only inside the bottom portions of the grooves, to thereby significantly reduce the resistance of the cell structure (e.g. by a factor of 2-4), which in turn allows for increasing a distance between the metal lines (extending perpendicular to, or generally intersecting with, the grooves' axis) to electrically connect the grooves. Indeed, provision of n+ regions only in such “vertical” grooves, whose regions are practically not light absorbing by themselves (due to the geometry of the bottom portion of the grooves which results in that practically light rays incident onto the bottom portion are only those of almost normal incidence, and thus a very small amount of light interacts with these regions), allows for increasing the level of doping. Preferably, these heavily doped n+ regions are further covered by a thin metal layer, which further reduces the series resistance, allowing for further increasing a distance between the perpendicular metal lines. Light reflected from the metal regions is further absorbed by side walls of the grooves, thus further increasing the device efficiency. The lightly doped n-type or alternatively p-type surface does not contribute to the resistive losses, as the distance between neighboring heavily doped n-type lines is about two orders of magnitude lower than the distance of about 1 mm between the metal lines in standard photovoltaic cells.

Increased distance between the perpendicular metal lines allows for reducing the number of these metal lines, for the lines of a given width and a given surface area of the photovoltaic cell, thus increasing the effective light collection area of the cell. On the other hand, the metal lines may be of varying width, such that each metal line is narrower at the central region of the cell and becomes wider towards the sides of the cell. These wider portions of the metal lines are thus located at the connection points of the lines to the bus lines. The bus lines can be “moved” outside the light collection surface of the photovoltaic cell further reducing the effect of shading, thus increasing the effective area of light collection.

Thus, the metal lines are allowed to be wider due to a need to provide a much smaller number of such lines per cell. Such metal lines can be configured with a varying width, e.g. can be of a trapezoid-like shape, with the width increasing from the center of the photovoltaic cell towards the periphery (sides) thereof, where the bus lines are placed. This configuration of the metal lines allows for further reduced shading of the light collection surface (increasing the effective area of the cell), while keeping the electrical resistance desirably low. The metal lines are configured to be relatively narrow at the central region of the cell area where the electric current is lower, and become wider at the periphery region of the cell close to the sides thereof where the current is higher (after collecting current from larger parts of the photovoltaic cell). Thus, the trapezoid or the like width-varying shape of the metal lines is appropriately selected to maintain substantially constant current density along the metal line while reducing the shading of the light collection surface. The fewer but wider trapezoidal-like shaped metal lines can be made significantly thicker than the much narrower lines in standard cells thus further reducing series resistance.

Thus, according to one aspect of the invention, there is provided a photovoltaic device comprising a semiconductor substrate having a patterned light collecting surface defining an array of spaced-apart substantially parallel first grooves, each having a bottom portion comprising a bottom surface and side walls extending from the bottom portion and being substantially perpendicular to the surface of the device, a doped semiconductor layer in the form of spaced-apart regions located on the bottom surfaces of the first grooves respectively.

The semiconductor substrate is typically a p-type wafer, and the doped semiconductor layer is a heavily doped n+-type layer. It should be stressed however that the same type of cells can be made of n-type silicon with p-type doping at the top surface.

Preferably, a metal layer in the form of spaced-apart regions is provided on top of the doped semiconductor regions respectively.

A bottom surface of the groove portion may and may not be planar. For example, it may have a tip-like shape.

Preferably, the first groove has a top portion extending from the sidewalls of the bottom portion and having a funnel-like shape (i.e. side walls of the top portion are tilted such that the cross sectional area of the top portion increases from the bottom portion towards the outer surface of the cell). As for the bottom portion of the first groove, it is shaped to define an elongated narrow cavity with the side walls thereof being substantially perpendicular to the bottom plane, i.e. perpendicular or forming a funnel like structure with a relatively small tilt of the side walls such that the cross sectional area of the bottom portion decreases from bottom surface towards the top portion.

The first grooves may be arranged with a space of about 10-20 micrometers between them.

A second array of metal lines which electrically connect the first grooves extend in a spaced-apart parallel relationship along a second axis substantially perpendicular to the first axis along which the first grooves are arranged. The metal lines (which are typically of a width of a few hundreds of micrometers) can be spaced a distance of at least a few centimeters from one another. The metal lines may be located in second wider grooves defined perpendicularly to the densely packed narrow grooves, extending along the bottom surfaces of the second grooves.

Preferably the metal lines are configured with a varying width, e.g. have a trapezoid-like geometry being narrower around the central part of the photovoltaic cell and wider at the sides (peripheral part) of the cell. In some embodiments, the width of the metal lines around the center of the cell is about one hundred micrometers, and the width at the sides of the cell may be close to one millimeter. It should be understood that the geometry/shape of the metal lines and the number and arrangement of these lines are selected in accordance with a desired resistance to be obtained along the lines for a desirably small number and low-density arrangement of such lines, to meet the requirements of the current density in the cell of given dimensions.

Considering a typical photovoltaic cell of size of 10 by 10 centimeters configured according to the present invention as described above, the metal lines may be spaced apart a distance of at least a few millimeters from one another. In some embodiments the metal lines may be spaced apart a distance of at least a few millimeters from one another. In some other embodiments, the metal lines may be spaced apart a distance of at least a few centimeters from one another. For example, the distance between the metal lines may be about 2.5 centimeters.

A bus line arrangement, composed of one or more bus lines, electrically connecting the metal lines, may be located in at least one (third) groove extending substantially parallel to the first axis.

According to some embodiments of the present invention, the bus line arrangement may be composed of two buses located outside the light collection surface at the opposite sides of the photovoltaic cell and substantially parallel to the first axis. Such bus lines are electrically connected to the metal lines extending along the second axis, intersecting with (e.g. being substantially perpendicular to) the first axis.

The effects of reduced series resistance and shading can reduce cumulative losses from about 12% to about 6%.

According to some other embodiments of the present invention, the photovoltaic cell is configured such as to eliminate a need for two bus lines, and uses a single bus line, extending substantially perpendicular to (generally intersecting with) the first axis along which the cell grooves of the photovoltaic device extend and carrying out the complete current collection from the photovoltaic device (from the array of cells). In the description below this single metal line is sometimes termed “bus line”, but it should be understood that it actually performs the function of perpendicular metal and bus lines of the alternative configurations. In this case, such a bus line is directly electrically connected to the metal regions in the cell grooves. This may result in lower manufacturing cost of the cell.

The above-described configurations of the photovoltaic device of the invention provides for obtaining combined series resistance and shading losses substantially not exceeding a few percentages, e.g. 6% or less. The efficiency loss may be as low as 5%.

According to another aspect of the invention, there is provided a photovoltaic device comprising a semiconductor substrate having a patterned surface defining an array of spaced-apart first grooves extending along a first axis, each groove having a bottom portion comprising a bottom surface and side walls extending from said bottom portion and being substantially perpendicular to said surface of the device, a doped semiconductor layer in the form of spaced-apart regions located on the bottom surfaces of said first grooves respectively; and an array of metal lines extending in a spaced-apart parallel relationship along a second axis substantially perpendicular to said first axis and being electrically coupled with said regions in the first grooves, said metal lines being spaced a distance of at least a few thousands of micrometers from one another.

According to yet another aspect of the invention, there is provided a photovoltaic device comprising: a semiconductor substrate having a patterned surface defining an array of spaced-apart first grooves, each having a bottom portion comprising a bottom surface and side walls extending from said bottom portion and being substantially perpendicular to said surface of the device; a doped semiconductor layer in the form of spaced-apart regions located on the bottom surfaces of said first grooves respectively; and a metal layer in the form of spaced-apart regions on top of said doped semiconductor regions respectively.

The invention also provides a method for manufacturing a photovoltaic device, the method comprising: patterning a light collecting surface of a semiconductor substrate, said patterning comprising creating a first array of first grooves arranged in a spaced-apart parallel relationship and extending along a first axis with a first distance between them, and a second array of second grooves arranged in a spaced-apart parallel relationship and extending along a second perpendicular axis with a second larger distance between them, each of the first grooves having a bottom surface and side walls extending from said bottom surface and being substantially perpendicular to said light collecting surface; forming a doped semiconductor layer in the form of spaced-apart regions located on the bottom surfaces of said first grooves respectively.

The formation of the doped semiconductor regions may be carried out in a single lithography step.

The method preferably further includes creation of a metal layer in the form of spaced-apart regions on top of the doped semiconductor regions in the grooves.

According to yet further aspect of the invention, there is provided a method for manufacturing a photovoltaic device characterized by combined series resistance and shading losses substantially not exceeding a few percentages, the method comprising patterning a light collecting surface of a semiconductor substrate, said patterning comprising creating a first array of first grooves arranged in a spaced-apart parallel relationship and extending along a first axis with a first distance between them, and a second array of second grooves arranged in a spaced-apart parallel relationship and extending along a second perpendicular axis with a second larger distance between them, each of the first grooves having a bottom surface and side walls extending from said bottom surface and being substantially perpendicular to said light collecting surface, and forming a heavily doped semiconductor layer in the form of spaced-apart regions located on the bottom surfaces of said first grooves respectively, and providing spaced-apart metal regions on top of said spaced-apart regions of the heavily doped semiconductor respectively.

As for the entire front surface of the device, except for the bottom of the trench, it may be formed with a lower concentration of n-type layer, for the collection of the photo generated free electrons in the p-substrate. Alternatively, the front surface may be p-type with slightly higher doping concentration than the p-type substrate, to form a potential barrier for the reduction of surface recombination.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1 is a schematic cross sectional illustration of a portion of a photovoltaic device of the present invention;

FIG. 2 is an image of the cross-section of a portion of a photovoltaic device configured according to the present invention;

FIG. 3 is a schematic illustration of light propagation scheme showing light interaction with a groove being a part of a photovoltaic device of the present invention;

FIGS. 4A-4C illustrate top views of photovoltaic devices based on the principles of the invention and configured according to 3 different examples respectively, wherein in FIG. 4A the bus lines collecting electrical energy from perpendicular metal lines are located within the light collection surface of the photovoltaic device; in FIG. 4B the metal lines are configured with a trapezoid shape (constituting an example of varying width metal lines) and the bus lines are located at the sides of the photovoltaic device outside the light collection surface, and in FIG. 4C the photovoltaic device utilizes a single metal bus line extending perpendicular to the grooves of the photovoltaic device; and

FIGS. 5A-5D exemplify a method of fabrication of the photovoltaic device of the present invention, wherein FIG. 5A illustrates the substrate after etching and metallization, FIG. 5B illustrates a resist layer applied on the substrate, FIG. 5C shows the remaining layer of the resist after partial ashing, and FIG. 5D illustrates a cross-section of the photo-voltaic cell after the metal lines have been formed.

### DETAILED DESCRIPTION OF EMBODIMENTS

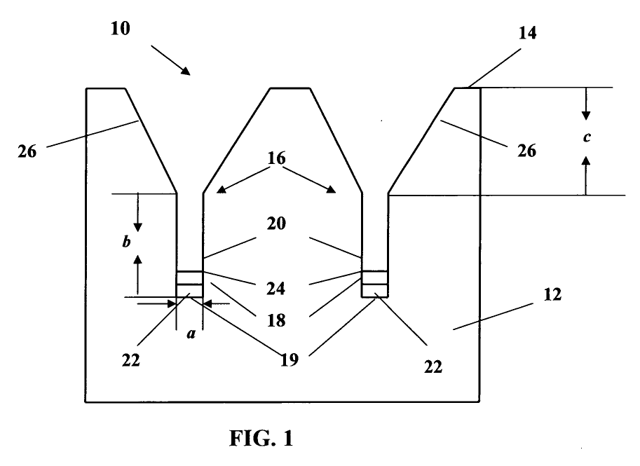

Referring to FIG. 1, there is schematically illustrated a cross sectional view of a photovoltaic device, generally designated 10, according to an embodiment of the invention. The device 10 includes one or more photovoltaic cells electrically connected in series. The cell(s) is/are fabricated in a semiconductor substrate (wafer) 12, typically silicon p-type substrate. The substrate 12 has a patterned surface 14, the pattern comprising an array of spaced-apart grooves 16. The groove 16 has a bottom portion 18 configured as a deep narrow cavity having a bottom surface 19 and side walls 20 substantially perpendicular to the surface 14 of the structure 10.

Such arrangement of the side walls 20 substantially perpendicular to the surface 14, or the so-called “substantially vertical” bottom portion 18 can be obtained by making the side walls 20 parallel to each other or arranged with a small angle between them. In the latter case, the configuration is such that a distance between the walls either increases or decreases along a direction from top to the bottom of the groove 16 (in other words, the bottom portion is either wider or narrower at the bottom thereof than at the top thereof). The bottom surface 19 may have a planar geometry, or a curved one, for example being shaped like a tip.

Preferably, the groove 16 has a top portion 26 extending from the side walls of the bottom portion and having a funnel-like shape (i.e. having tilted side surfaces extending along two intersecting planes) such that the top portion is wider at the distal part thereof (at the external surface 14 of the cell) than at the proximal part thereof (where it interfaces with the bottom portion). It should be understood that the provision of the funnel-like top portion is optional, and alternatively, light can be absorbed by planar surface regions 14 of the substrate in between the grooves 16.

When the surface 14 of the cell structure 10 is exposed to electromagnetic radiation, the side walls of the grooves 16 (e.g. including also tilted surfaces of the top groove portion 26 if any) operate as the active, light collecting area of the device, while the bottom surface of the bottom portion 18 of the groove practically does not collect incident radiation but acts as a reflective/scattering surface, where most of the radiation reflected from it hits the side walls and is absorbed by the semiconductor. The cross sectional dimension (width) a of the bottom portion 18 of the groove may be of a few micrometers (e.g. 1-5 μm), and the depth (height) b of this groove portion 18 may be 2-3 times larger, e.g. about 4-15 μm. As for the depth (height) of the top groove portion 26 it may be about 8-20 μm.

The device 10 further includes a heavily doped n+ layer in the form of spaced-apart regions 22 located only at the bottom of the groove portion 18. Preferably, the device 10 further includes a metal layer in the form of spaced-apart regions 24 on top of n+ regions 22. It should be understood, and is also indicated above that the present example refers to a semiconductor substrate which is typically a p-type wafer, and the doped semiconductor layer is a heavily doped n+-type layer; however the principles of the invention can be implemented or made of n-type silicon with p-type doping at the top surface.

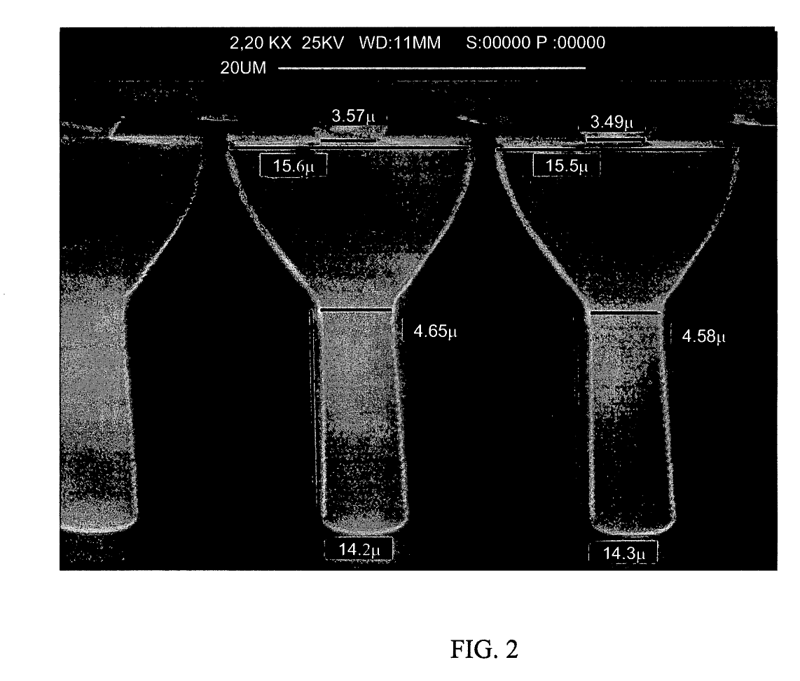

Reference is made to FIG. 2 showing an image of a portion of an experimental photovoltaic device configured according to the present invention. The structure of the grooves is generally as described above, namely the groove has bottom and top portions, where the top portion has a funnel-like geometry with the width thereof increasing towards the outer surface, and the bottom portion is substantially “vertical”. In this example, the latter configuration is achieved by using a small tilt of the side walls of the bottom portion to make the width of this portion decreasing upwards. The width and depth of the grooves may vary, providing varying collective resistivity of the photovoltaic cell.

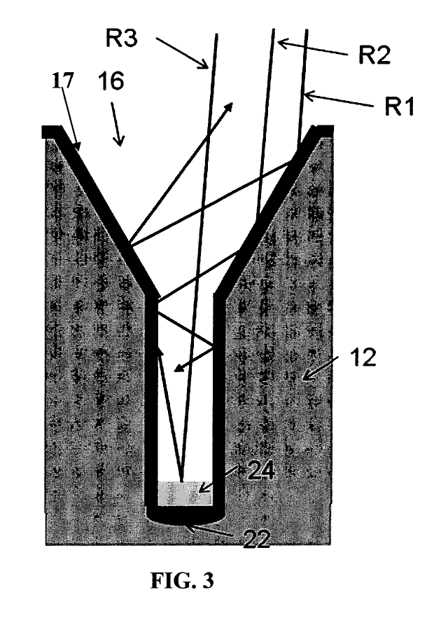

Reference is now made to FIG. 3 which illustrates the propagation of light rays onto and through a groove 16, made in the semiconductor substrate 12, of a photovoltaic cell according to the present invention. This figure shows three light rays R1, R2 and R3 falling on the groove structure 16. The light rays may be incident on different locations on the groove structure and may be reflected from the groove surface. Additionally, although not shown here, light rays may reach the surface of the cell from different directions, for example, at different times of a day. In this figure, light ray R1 is reflected twice from two successive locations of interaction with the surface. As shown in the figure, the device preferably includes an antireflection layer 17 on the various cell surfaces, thus after the two interactions most of the light will be absorbed in the cell and converted to electrical energy by the cell, while only a small fraction of the light may be reflected out of the photovoltaic cell. Ray R2 is successively reflected a few times from the surface of the groove, each time a portion of the light is converted to electrical energy, and finally the light ray R2 is completely absorbed by the semiconductor substrate and is converted to electricity, even if there is no efficient antireflection layer on the vertical walls. A small fraction of the light interacting with the cell, exemplified by ray R3, may impact directly on the metallic layer 24 at the bottom surface of the groove 22. This portion of the light is mostly formed by light propagating normally to the light collection surface 14, and is therefore mostly reflected from the metallic layer 24. However, most of this light will hit the side walls and is absorbed in the semiconductor. In case there is no metal layer inside the groove, the light ray R3 would interact with the n+ regions and would be partly absorbed and partially reflected. The reflected portion of light ray R3 is typically collected at the side walls 20 of the groove, and the optical energy is converted to electricity.

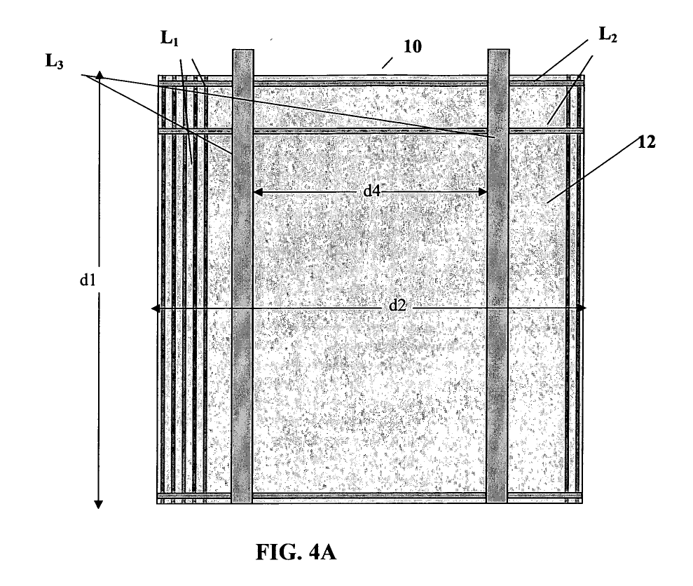

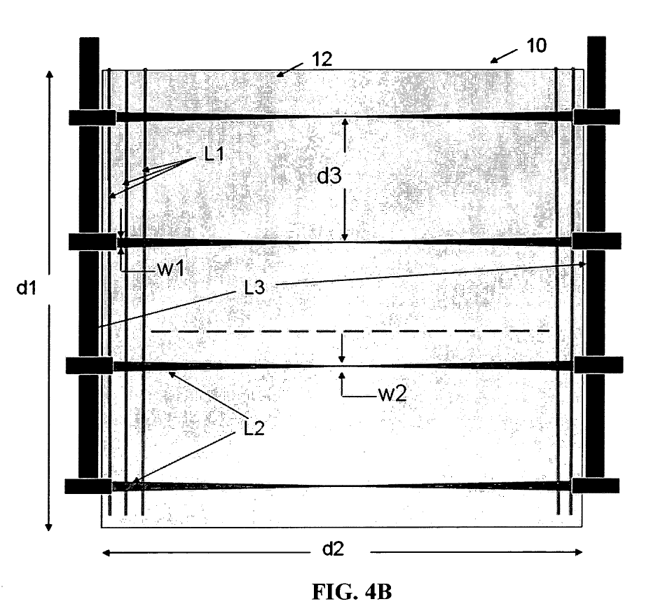

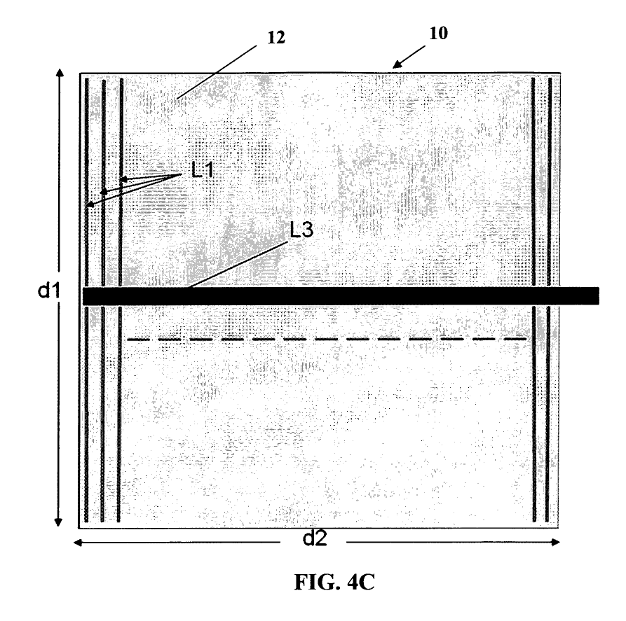

Reference is now made to FIGS. 4A-4C exemplifying the top view of the photovoltaic device 10 according to three embodiments of the present invention respectively. In the example of photovoltaic device of FIG. 4A, bus lines L3 are arranged in a spaced-apart parallel relationship within the light collection surface of the photovoltaic cell with a distance d4 from one another equal to half the cell width d2. Also, in this example, the metal lines have substantially the same width along the line. FIG. 4B illustrates another embodiment in which the perpendicular metal lines L2 have a varying width, e.g. trapezoid-like shape. Also, in this example, the bus lines are placed on the sides of the photovoltaic device being outside the light collection surface. It should be understood that placing the bus lines outside the light collection surface can also be achieved in the example of FIG. 4A. The distance between the bus lines and thus their location with respect to the light collection surface can be controlled using the principles of the invention (geometry and material configuration of the grooves) to meet the requirements of total resistance and shadowing. In the embodiment illustrated in FIG. 4C, a single metal line (“bus line”) is placed along the second axis of the photovoltaic device performing the function of the multiple perpendicular lines and bus lines of the alternative configurations. The possibility of using only one such metal (bus) line in the cell unit, or moving the two bus lines outside the light collection surface of the cell unit, is a direct result of a significantly reduced series resistance.

The semiconductor substrate of the photovoltaic device 10 of FIG. 4A is patterned to provide the above described patterned surface 14. The embodiment illustrated in FIG. 4B provides a further reduction in shading losses which is achieved by configuring the perpendicular metal lines L2 with a varying width and also by placing the bus lines L3 at the sides of the photovoltaic cell outside its light collection surface. This is because the fill factor of metalized region within the light collection surface is provided, due to the fact that less area of the light collection surface is covered by the metal lines because these lines are relatively narrow over most of this surface and of a smaller number with a relatively large distance between them (due to the provision of narrow metal lines L1 as a layer on the bottom of the grooves 16).

More specifically, the metal lines L2 are configured with a trapezoid shape with width w1, e.g. of about a millimeter, at the sides of the cell and width w2 of about a few hundreds of micrometers at the center of the cell. The current collected by the metal lines L2 is accumulated from the center of the cell to the sides. The width of the metal lines L2 can therefore be narrow at the center of the cell w2 thus reducing shadowing of the light collection surface and contributing to the effective area of the cell. At the sides of the photovoltaic cell, the metal lines are wider in order to reduce the resistivity at higher current accumulated along the second axis of the cell and maintain a constant current density along the line L2.

It should be made clear that the trapezoidal-like shape of the metal lines L2 cannot be implemented in standard solar cell technology. This is because the metal lines, which are close to each other and thus exist in a large number, are kept at minimum width to reduce their shading.

Bus lines L3 are positioned at the sides of the photovoltaic cell and therefore practically do not screen a part of the light collection surface of the cell from incoming light. This is possible since the bus lines L3 are connected only to a few metal lines L2. These few metal lines are much wider than corresponding lines in the standard cell unit configuration, consequently they can be made much thicker with the result of significantly smaller series resistance. The soldering positions (nodes) may be larger without increasing the shadowing of the device.

The choice of distance d3 between the metal lines L2 and similarly the number of the metal lines is dictated mainly by the width of the grooves 16 and the metal lines L1 within the grooves. The wider the grooves, the lower the resistance of the cell structure, and the use of a fewer metal lines in the cell is sufficient. Still, wider grooves should preferably be deeper in order to reduce reflection of light from the n+ or metal layer on the bottom of the groove.

By providing the photovoltaic cell with appropriately wide and deep grooves 16 (for example grooves of 4 micrometers or more in width and 12 micrometers or more in depth in a 10×10 centimeters light collection surface), and providing metal lines L1 on the bottom of the grooves, the electrical conductivity within the cell might be sufficient to allow a single bus line for directly collecting the electrical energy from the grooves with no intermediate collection and transfer of energy by the perpendicular metal lines L2. Such an embodiment is illustrated in FIG. 4C. More specifically, in the embodiment illustrated in FIG. 4C a single metal bus line L3 extends along the second axis of the photovoltaic cell 10, substantially perpendicular to the direction of the metal lines L1 placed on the bottom of the grooves.

The advantages/disadvantages of either one of the above described embodiments relative to others relate basically to the efficiency obtainable by the cell unit on one hand and the manufacturing costs of the cell unit on the other hand.

Table 1 shows the resistive and shading related efficiency losses of exemplary photovoltaic cells of the present invention constructed generally according to the embodiment illustrated in FIG. 4B, as compared to a photovoltaic cell of the conventional configuration (i.e. no grooves geometry as described above, provision of lightly doped n+ layer along the entire or most of the light collection surface rather than only in the grooves). The photovoltaic device configurations considered in this comparison analysis include two examples for metallization configurations of the photovoltaic device of the present invention (i.e. utilizing metal regions on top of n+ regions in the bottom portion of the grooves), and the commonly used dimensions as follows:

(1) 10×10 cm² for a photovoltaic device which does not utilize an additional light concentrator (1^{st}, non-concentrating configuration), in this configuration d1 and d2 are both equal to 10 centimeters, and

(2) 10×3.3 cm² for the device with ×10 concentrator (2^{nd}, concentrating configuration), wherein d1 equals 10 centimeters and d2 equals 3.3 centimeters.

The table compares the calculated efficiency losses in percents resulting from the resistance of different elements and shading of the light collection surface of the cell unit for both the photovoltaic cells with no concentration and cells configured to work with 10 times concentration of light.

TABLE 1

| Efficiency losses | No concentration | | X10 concentration | |
|---|---|---|---|---|
| (EL percent) | Standard cell | New cell | Standard cell | New cell |
| R-substrate | 0.26 | 0.26 | 2.6 | 2.6 |
| R-grooves (L1) | 3 | 0.54 | 1.8 | 1.62 |
| R-metal (L2) | 0 | 1.5 | 0 | 1.25 |
| S-grooves (L1) | 0 | 1 | 0 | 1 |
| S-metal (L2) | 3.6 | 1.6 | 8 | 1.65 |
| S-bus (L3) | 5 | 0.5 | 10 | 1 |
| Total EL | 11.8 | 5.4 | 22.4 | 9.2 |

The efficiency loss is associated with two main effects, one is the resistance (R) of the materials in which electric current flows, and the other is shading (S) of the light collection surface. Table 1 shows the calculated values of efficiency loss, EL, associated with the following parameters: the electrical resistance of the semiconductor substrate, (R-substrate); the conduction/resistance of the grooves (in case of the configuration of the present invention) or the diffusion of charge carriers into the semiconductor in case of the conventional configuration, (R-groove); and the resistance of the metal lines L2 collecting the current, (R-metal). It should be noted that this comparative analysis does not include the resistance of the bus lines, because it is relatively low as these lines are much thicker than the other metal lines in the cell unit. The table also shows calculated losses resulting from shading of the light collection surface, S; and losses resulting from reflection of light from reflective parts of the cell unit, S-groove. The elements screening the light collection surface from incoming light and thus causing shading are formed by the metal layer at the bottom of the grooves, lines L1 which reflect a part of the incident light preventing its absorption (S-groove), the metal lines L2 collecting current (S-metal) and the buses L3 (S-bus). In the embodiment illustrated in FIG. 4B, where the buses are positioned at the sides of the cell outside the light collection surface, only the points of connection of the metal lines and the buses block the light propagation into the device, thus the efficiency loss value associated with the shadowing by the bus lines is as low as 0.5%.

The resistance of the semiconductor substrate (R-substrate) is not affected by the configuration of the present invention, as compared to conventional configuration, and therefore this parameter is the same in the invented and conventional photovoltaic cell units. The present invention provides for improved efficiency of the photovoltaic cell unit by reducing the resistance and diffusion of charge carriers into the substrate by introducing the groove geometry, high n+ doping only within the grooves, and can also further improve to the efficiency owing to the provision of a metal layer on top of n+ regions at the bottom surface of the grooves (R-grooves). As indicated above, shading associated losses may be a result of light reflection from the metal layer on the bottom of the grooves (S-grooves), and from shading of the active area by the metal lines (S-metal) and the buses (S-bus). In a photovoltaic cell unit according to the conventional configuration the light collection surface actually does not contain any reflecting features and thus the shadowing losses caused by reflection are almost zero (S-grooves). This is while about 1% of the optical energy might be reflected from the metal layer at the bottom of the grooves of a photovoltaic cell according to the present invention. This estimate value of about 1% is much smaller than the number obtained from the relative width of this metal line with respect to the trench pitch. Two reasons are responsible for this deviation: A) most of the light reflected from the metal at the bottom of the trench is absorbed by the vertical trench walls; B) In the case of fixed solar panels, most of the time there is no direct line of sight from the sun to the metal line. Furthermore, in concentrated systems, most light reaches the cell at slanted angles. On the other hand, the present invention allows for significantly reducing the number and density of the metal lines L2, even eliminating a need for these lines at all (see FIG. 4C), and allows for placing the bus lines outside the light collection surface (see FIG. 4B), thus dramatically reducing the total effect of shading the light collecting surface.

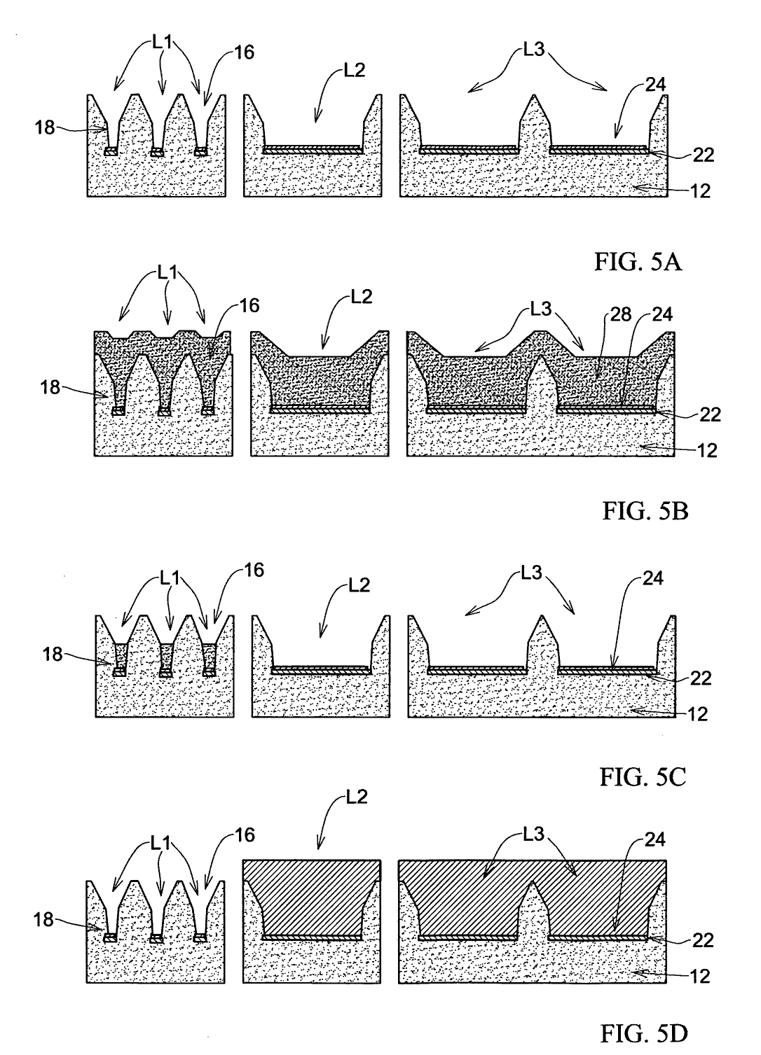

Reference is now made to FIGS. 5A-5D showing one approach of the fabrication of a photovoltaic cell unit/device according to the present invention using one lithographic step of more than 1 micron minimum dimension for the formation of deep grooves for lines L1 (grooves 18), L2 and L3. FIG. 5A illustrates the substrate structure after a first metallization process (deposition of metal lines L1, L2 and L3 in the respective grooves). FIG. 5B shows the structure after resist application onto the outer surface of the device. In FIG. 5C, the structure is shown after controlled ashing of the resist, resulting in removal of the resist from the grooves corresponding to metal lines L2 and L3 while leaving the resist regions above metal lines L1 due to a small width of the respective grooves. FIG. 5D illustrates a cross section of the photovoltaic cell structure after additional deposition of metal along lines L2 and L3 to achieve the desired thickness of these lines. As shown in this figure, metal lines L1 remain of the initial thickness, because resist on top thereof prevented deposition of additional metal at those regions; this resist is then removed in the conventional manner.

The above technique eliminates a silk printing step thus reducing manufacturing costs. There is direct correlation between the manufacturing process and the cells' layout. The groove dimensions under the thick metal buses are based on the preferred metallization process (metal on top of n+ regions in the grooves) on the one hand, and on the other hand are dictated by the goal of minimizing the junction area under the metal buses, as it does not contribute to the photocurrent and consumes forward bias diode current.

FIG. 5A shows concurrent creation of grooves for lines L1, the metal lines L2 intersecting with lines L1, and the buses L3 extending parallel to lines L1. The bus lines L3 of a desired width may be formed by two or more (two in the present example) metal regions formed in the locally adjacent grooves. After the formation of n+ layer 22 at the bottom of the grooves 18, about 1 μm thickness metal layer 24 may be formed by electroless plating on the n+ regions only. In FIG. 5B, a positive photoresist 28 is applied with no light exposure followed by bake. Controlled ashing process strips the photoresist from the wafer surface regions outside the grooves, as well as from the bottom of the wide grooves (those of lines L2 and L3), thus leaving the photoresist only in the ˜1 μm width grooves 18, as shown in FIG. 5C. This is because at the end of the photoresist formation thicker resist will be in the narrow grooves, and the ashing process is slower inside the narrow grooves. In FIG. 5D, an electro/electroless process is used to plate ˜30 μm of metal on the exposed thin metal surface. Deposited thick metal lines on narrow spaced wide grooves will be shortened creating an even wider bus line.

Thus, the present invention provides a novel configuration of a photovoltaic device and a method of its manufacture. This device has deep narrow and long grooves (groove portions 18), and possibly also funnel-shaped groove top-portions, in the front surface of the device with the heavily doped emitter (n+ layer) located only in the bottom of the grooves, and preferably also metal layer 24 deposited selectively on the bottom of the groove (on top of n+ regions) with the result that most of light reflected from these metal lines hits the side walls of the groove instead of escaping the device. The outer surface of the deposited metal layer 24 is preferably of a certain roughness (not smooth) in order to effect light scattering therefrom, and is also not necessarily flat but in the form of a tip. This structure (having deep narrow parallel groove portions 18 with the metal coated carrier emitter 22, 24, and possibly also having funnel shape impacts on the cell efficiency) reduces the shading in two aspects: (1) about 90% of the reflected light from the buried metal line hits the side walls of the grooves and is absorbed in the silicon, hence contributing to the photocurrent; and (2) the resistance of these buried metal lines is about three orders of magnitude lower than the heavily doped n+ line of the same dimensions. As a result, the spacing between the perpendicular metal lines (L₂ in FIGS. 4A-4B and FIGS. 5A-5D, or slots S₂ in FIG. 6) can be significantly increased (up to 2.5 centimeters in some embodiments), as well as these metal lines may not be used at all (see FIG. 4C), and the bus lines may be placed outside of the light collection surface of the device or a single bus line may be used. This leads to a point that in a given cell unit (i.e. given dimensions of the light collection surface) there are much less metal lines running on top of the light collection surface, being perpendicular to the grooves or parallel thereof, with significant reduction in the shading loss associated with these lines. The cumulative increase in cell efficiency due to these two factors is estimated to be more than 5%

Turning back to FIG. 5A, showing an example of the manufacture of the photovoltaic structure, the following should be noted. The first grooves having a deep narrow substantially parallel-walls portion and possibly also a top funnel like portion are dogged densely in the front (light collecting) side of the silicon wafer; the first and second grooves as well as those for the bus lines are created using a common lithography step. Preferably, the invention also utilizes Reactive Ion Etching (RIE) which is the selective etching applied through a patterned layer serving as an etching mask. Thus, the patterned n+ layer in the form of n+ regions on the bottom of the grooves only is created in the same lithography step. Alternatively, the wider perpendicular metal lines L2 and two metal buses L3 can be deposited using the standard silk printing or inkjet techniques. The photovoltaic device of the present invention is characterized by low series resistance on the one hand and minimal shading of the cell active region on the other hand as most of the radiation reflected from this bottom metal layer is reabsorbed by the silicon protruding side walls.

Those skilled in the art will readily appreciate that various modifications and changes can be applied to embodiments of the invention as hereinbefore described without departing from its scope defined in and by the appended claims.

1. A photovoltaic device comprising: a semiconductor substrate having a patterned light collecting surface defining an array of spaced-apart substantially parallel first grooves, each having a bottom portion comprising a bottom surface and side walls extending from said bottom portion and being substantially perpendicular to said surface of the device; and a heavily doped semiconductor layer in the form of spaced-apart regions, each extending along the bottom surface of the respective first groove.

2. The device of claim 1, wherein said semiconductor substrate is a p-type wafer, and said doped semiconductor layer is heavily doped n+-type layer.

3. The device of claim 1, comprising a thin metal layer in the form of spaced-apart regions, each region being located on top of said doped semiconductor region in a respective one of said first grooves.

4. The device of claim 1, wherein the first groove has a top portion extending from said side walls of the bottom portion and having a funnel-like shape such that side walls of said top portion are tilted with respect to said side walls of the bottom portion and a cross sectional dimension of the top portion increases from a bottom to a top thereof.

5. The device of claim 1, wherein said bottom portion of the first groove defines an elongated narrow cavity.

6. The device of claim 5, wherein said side walls of the bottom portion are either substantially parallel to each other, or are slightly tilted.

7. The device of claim 1, wherein said first grooves are arranged with a space of about 10-20 micrometers between them.

8. The device of claim 3, comprising a single metal line, extending along a second axis intersecting with a first axis of said first grooves and being electrically coupled with said spaced-apart metal regions in the first grooves for collecting electric current generated in the device.

9. The device of claim 1, comprising an array of metal lines extending in a spaced-apart parallel relationship along a second axis intersecting with a first axis of the first grooves and being electrically coupled with said spaced-apart regions in the first grooves.

10. The device of claim 9, comprising an array of spaced-apart second grooves extending along said second axis.

11. The device of claim 10, wherein said metal lines extend along bottom surfaces of said second grooves.

12. The device of claim 9, wherein said metal lines have a width of a few hundreds of micrometers and are spaced a distance of at least a few tenths of millimeters from one another.

13. The device of claim 9, wherein said metal lines have a width of a few tens of micrometers and are spaced a distance of at least a few centimeters from one another.

14. The device of claim 9, wherein said metal lines are configured with a varying-width along said metal line.

15. The device of claim 14, wherein said metal lines with varying width are configured to be narrower at the central region of the light collection surface and wider at the periphery thereof.

16. The device of claim 9, wherein said metal lines are connected to one metal bus line in the center of the cell, or connected to two metal bus lines located outside the light collection surface.

17. The device of claim 1, wherein combined series resistance and shading losses substantially not exceeding a few percentages.

18. The device of claim 1, wherein combined series resistance and shading losses substantially not exceeding 6%.

19. A photovoltaic device comprising:
a semiconductor substrate having a patterned surface defining an array of spaced-apart first grooves extending along a first axis, each groove having a bottom portion comprising a bottom surface and side walls extending from said bottom portion and being substantially perpendicular to said surface of the device,
a doped semiconductor layer in the form of spaced-apart regions, each of said regions extending along the bottom surface of a respective one of said first grooves; and
an array of thicker metal lines extending in a spaced-apart parallel relationship along a second axis intersecting with said first axis and being electrically coupled with said regions in the first grooves, said metal lines being spaced a distance of at least a few hundreds of micrometers from one another.

20. The device of claim 19, wherein said thicker metal lines are configured with a varying width along the line.

21. A photovoltaic device comprising:
a semiconductor substrate having a patterned surface defining an array of spaced-apart first grooves, each having a bottom portion comprising a bottom surface and side walls extending from said bottom portion and being substantially perpendicular to said surface of the device,
a doped semiconductor layer in the form of spaced-apart regions, each of said regions extending the bottom surfaces of a respective one of said first grooves; and
a metal layer in the form of spaced-apart regions, each metal region being located on top of the doped semiconductor region in a respective one of said first grooves.

22. A method for manufacturing a photovoltaic device, the method comprising:
patterning a light collecting surface of a semiconductor substrate, said patterning comprising creating a first array of first grooves arranged in a spaced-apart parallel relationship and extending along a first axis with a first distance between them, and a second array of second grooves arranged in a spaced-apart parallel relationship and extending along a second perpendicular axis with a second larger distance between them, each of the first grooves having a bottom surface and side walls extending from said bottom surface and being substantially perpendicular to said light collecting surface; forming a doped semiconductor layer in the form of spaced-apart regions such that each region of said doped semiconductor layer extends along the bottom surface of a respective one of said first grooves.

23. The method of claim 22, wherein said formation of the doped semiconductor regions comprises a single lithography step.

24. The method of claim 22, comprising creating a metal layer in the form of spaced-apart regions each metal region being located on top of said doped semiconductor region in the respective one of the first grooves.

25. The method of claim 22, wherein said patterning comprises creation of the first grooves, each having a top portion extending from said side walls of the bottom portion and having a funnel-like shape.

26. A method for manufacturing a photovoltaic device characterized by combined series resistance and shading losses substantially not exceeding a few percentages, the method comprising:
patterning a light collecting surface of a semiconductor substrate, said patterning comprising creating a first array of first grooves arranged in a spaced-apart parallel relationship and extending along a first axis with a first distance between them, and a second array of second grooves arranged in a spaced-apart parallel relationship and extending along a second perpendicular axis with a second larger distance between them, each of the first grooves having a bottom surface and side walls extending from said bottom surface and being substantially perpendicular to said light collecting surface; and
forming a heavily doped semiconductor layer in the form of spaced-apart regions each region extending along the bottom surface of a respective one of said first grooves; and
providing spaced-apart metal regions each metal region being located on top of the region of the heavily doped semiconductor in the respective one of the first grooves.
